(19) United States
(12) Patent Application Publication
(10) Pub. No.: US 2019/0131570 A1
(43) Pub. Date: May 2, 2019

(54) ORGANIC LIGHT EMITTING DIODE CUSHING FILM

(71) Applicant: 3M INNOVATIVE PROPERTIES COMPANY, St. Paul, MN (US)

(72) Inventors: Richard Y. Liu, Woodbury, MN (US); Nathaniel I. Lehn, White Bear Lake, MN (US); Roger A. Grisle, Woodbury, MN (US); Benjamin J. Bending, St. Paul, MN (US)

(21) Appl. No.: 16/094,048

(22) PCT Filed: Apr. 10, 2017
(86) PCT No.: PCT/US2017/026765

§ 371 Date: Oct. 16, 2018

Related U.S. Application Data
(60) Provisional application No. 62/329,779, filed on Apr. 29, 2016.
(60) Provisional application No. 62/404,599, filed on Oct. 5, 2016.

(51) Int. Cl. H01L 51/52; C08J 9/10; H01L 51/00

(52) U.S. Cl. CPC H01L 51/5253; C08J 9/103; H01L 51/0043; H01L 51/0035; H01L 51/529; C08J 2207/06; H01L 2251/558; C08J 2205/044; C08J 2205/052; C08J 2203/04; C08J 2309/06; H01L 51/52

(57) ABSTRACT

An organic light emitting diode (OLED) cushioning film including a foamed layer is described. The foamed layer includes an olefin-styrene block copolymer at 30 to 80 weight percent and a tackifier at 15 to 60 weight percent. The tackifier has a softening point of at least 130° C. A light emitting article including an OLED layer laminated to the OLED cushioning film is described.

### BACKGROUND

A foamed layer may be utilized in an Organic Light Emitting Diode (OLED) display to prevent mechanical impacts from damaging an active OLED layer in the display.

### SUMMARY

In some aspects of the present description, an organic light emitting diode (OLED) cushioning film including a foamed layer is provided. The foamed layer includes an olefin-styrene block copolymer at 30 to 80 weight percent and a tackifier at 15 to 60 weight percent. The tackifier has a softening point of at least 130° C.

In some aspects of the present description, a light emitting article including an OLED layer laminated to an OLED cushioning film with an adhesive layer is provided. The OLED cushioning film includes a foamed layer which includes an olefin-styrene block copolymer at 30 to 80 weight percent and a tackifier at 15 to 60 weight percent. The tackifier has a softening point of at least 130° C. The adhesive has air-bleed channels adjacent the OLED layer.

### BRIEF DESCRIPTION OF THE DRAWINGS

FIGS. 1-3 are schematic cross-sectional views of Organic Light Emitting Diode (OLED) cushioning films; and

FIG. 4 is a schematic cross-sectional view of a light emitting article including an OLED cushioning film.

### DETAILED DESCRIPTION

In the following description, reference is made to the accompanying drawings that forms a part hereof and in which various embodiments are shown by way of illustration. The drawings are not necessarily to scale. It is to be understood that other embodiments are contemplated and may be made without departing from the scope or spirit of the present disclosure. The following detailed description, therefore, is not to be taken in a limiting sense.

In some embodiments of the present description, an organic light emitting diode (OLED) cushioning film including a foamed layer is provided. The foamed layer includes an olefin-styrene block copolymer at 30 to 80 weight percent and a tackifier at 15 to 60 weight percent. The tackifier has a softening point of at least 130° C., or at least 135° C., or at least 140° C. The softening point of the tackifier may also be less than 170° C. or less than 160° C. According to the present description, it has been found that utilizing such mixtures of olefin-styrene block copolymers and tackifiers with relatively high (at least 130° C.) softening points give improved damping performance in OLED cushioning films compared to polyurethane foams, for example, which often have relatively poor mechanical strength.

In some embodiments, the olefin-styrene block copolymer includes styrene blocks at 5 to 50 weight percent, or at 8 to 40 weight percent, or at 10 to 30 weight percent, or at 10 to 20 weight percent. In some embodiments, the olefin-styrene block copolymer comprises olefin blocks selected from the group consisting of ethylene, propylene, isoprene, octane, butylene, and copolymers thereof. In some embodiments, the olefin-styrene block copolymers are linear triblock copolymers with styrene blocks on opposite ends of an olefin block. Suitable olefin-styrene block copolymers include those available from KRATON Performance Polymers Inc., Huston, Tex., such as KRATON D1161 P which is a clear, linear triblock copolymer based on styrene and isoprene with a polystyrene content of 15 percent. Other suitable olefin-styrene block copolymers include diblock copolymers, multiblock copolymers, star-shaped block copolymers, and branched block copolymers.

In some embodiments, the foamed layer includes the tackfier at no less than 15 weight percent, or at no less than 20 weight percent, or at no less than 25 weight percent and at no more than 60 weight percent, or no more than 55 weight percent, or no more than 50 weight percent. The tackifier may be any suitable compound that is typically used for increasing the tack or stickiness of a layer. Suitable tackifiers include C5 hydrocarbons, C9 hydrocarbons, aliphatic resins, aromatic resins, terpenes, terpenoids, terpene phenolic resins, rosins, rosin esters, and combinations thereof. Suitable tackifiers include CUMAR 130, which has a softening point of 130° C. and which is available from Neville Chemical Company, Pittsburgh, Pa.; ARKON P140 which has a softening point of 140° C. and which is available from Arakawa Europe GnbH, Germany; CLEARON P150 which has a softening point of 150° C. and which is available from Yasuhara Chemical Co., Japan; and ENDEX 160 which has a softening point of 160° C. and which is available from Eastman Chemical Company, Kingsport, Tenn. In some embodiments, the tackifier is a terpene phenol resin such as SP-560 which has a softening point of 155° C. and which is available from SI Group Inc., Schenectady, N.Y.

The tackifiers can be a mixture of two or more tackifier compounds selected to give the mixture the desired softening point. The softening point for a mixture can be estimated by interpolation of softening points for the individual tackifier compounds. In some embodiments, the tackifier is a mixture of two or more tackifier compounds and the mixture has a softening point in a range of 130° C. to 170° C., or in a range of 130° C. to 160° C., or in a range of 140° C. to 160° C. Tackifiers suitable for use in mixtures that can be utilized include mixtures of the tackifiers described elsewhere herein. Suitable tackifiers include the hydrocarbon resin tackifiers and the rosin resin tackifiers available from Eastman Chemical Company, Kingsport, Tenn., and suitable mixtures of these tackifiers.

As used herein, the softening point of a tackifier, or of a mixture of tackifier compounds, is the softening point as determined using a ring and ball softening test. Unless indicated differently, the ring and ball softening test is the test method specified in the ASTM E28-14 test standard.

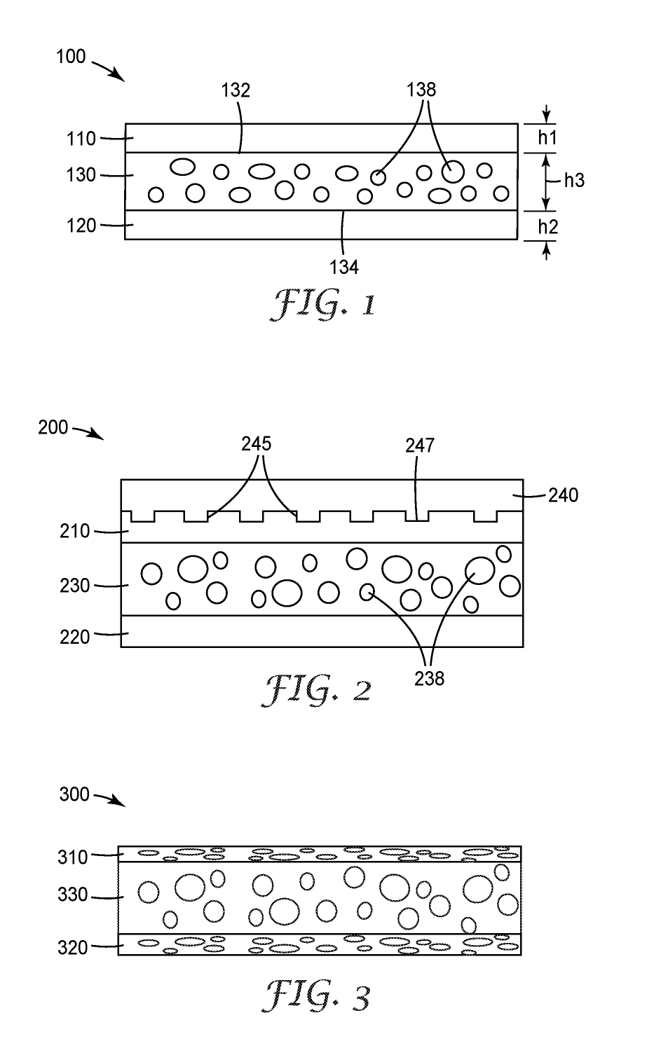

FIG. 1 is a schematic cross-sectional view of OLED cushioning film 100 including first and second layers 110 and 120 disposed on a foamed layer 130. One or both of the first and second layers 110 and 120 may be adhesive (e.g., pressure sensitive adhesive layers or heat-activated adhesive layers) or may be non-adhesive (e.g., non-tacky) layers, or may optionally be omitted. First layer 110 is disposed on first major surface 132 of foamed layer 130 and second layer 120 is disposed on second major surface 134 opposite the first major surface 132. The foamed layer 130 includes a plurality of cells 138 which may be filled with air or nitrogen or inert gases. The foamed layer 130 includes an olefin-styrene block copolymer at 30 to 80 weight percent and a tackifier having a softening point of at least 130° C. at 15 to 60 weight percent.

The OLED cushioning film 100 can be formed by coextruding each of the first and second layers 110 and 120 and the foamed layer 130. In other embodiments, the foamed layer 130 is formed separately from the first and second layers 110 and 120 and then the first and second layers 110 and 120 are laminated to the foamed layer 130 using a roll-to-roll laminator, for example. In still other embodiments, the first and second layers 110 and 120 are omitted.

In some embodiments, the foamed layer is made by including a foaming agent in the composition used to form the foamed layer 130. The foaming agent may include one or more of a surfactant, a chemical foaming agent, a blowing agent or any agent that can form gas in the layer. In some embodiments, the foaming agent is included in the composition at 0.5 to 6.0 weight percent. Suitable foaming agents include azodicarbonamide, sodium bicarbonate, citric acid, and ECOCELL-P which is available from Polyfil Corporation, Rockaway, N.J. In alternative embodiments, the plurality of cells 138 in the foamed layer 130 are formed by direct injection of gas into a composition which is extruded to form the foamed layer 130.

In some embodiments, the foamed layer 130 has a density substantially lower than the density of the polymers utilized in the foamed layer 130. For example, the polymers of the foamed layer 130 may have a density of about 1.2 g/cc and the foamed layer 130 may have a density below 1.0 g/cc. In some embodiments, the foamed layer 130 has a density in a range of 0.5 to 0.9 glee, or in a range of 0.55 to 0.9 glee, or in a range of 0.6 to 0.9 g/cc, or in a range of 0.55 to 0.85 g/cc, or in a range of 0.6 to 0.85 glee, or in a range of 0.6 to 0.8 glee. In some embodiments, plurality of cells 138 have an average (arithmetic average over all cells) cell size between 5 micrometers and 100 micrometers, or between 5 micrometers and 75 micrometers, or between 5 micrometers and 50 micrometers, or between 5 micrometers and 30 micrometers, or between 10 micrometers and 30 micrometers. The cell size is the largest dimension (e.g., diameter) of the cell. In some embodiments, the foamed layer 130 has a porosity (percent voided volume or percent volume containing a gas phase) in a range of 5 to 50 percent, or in a range of 10 to 40 percent, or in a range of 10 to 35 percent, or in a range of 10 to 30 percent. The plurality of cells 138 may be spherical, elliptical, or irregular shaped, for example. The plurality of cells 138 may be distributed substantially randomly and/or substantially uniformly in the foamed layer 130. The cells may be described as being substantially uniformly distributed if, for example, each spherical region in the interior of the foamed layer 130 having a diameter of 5 times the average cell size has an approximately same number of cells in the region. In some embodiments, at least a majority of the cells 138 are closed cells. In some embodiments, at least 50 percent, or at least 75 percent, or at least 90 percent, or substantially all of the cells 138 are closed cells.

The first layer 110 has a thickness h1, the second layer 120 has a thickness h2, and the foamed layer 130 has a thickness h3. In some embodiments, each of h1 and h2 is in a range of 0.05 to 1, or 0.1 to 0.5, or 0.12 to 0.35 times the thickness h3. In some embodiments, the thickness h3 of the foamed layer 130 is in a range of 30 micrometers to 1000 micrometers, or in a range of 40 micrometers to 500 micrometers, or in a range of 50 micrometers to 200 micrometers.

In some embodiments, first layer 110 comprises a non-tacky thermoplastic resin. This resin may comprise a polyolefin, polyester, polyurethane, polyamide, acrylate, or any suitable mixture, copolymer or modification thereof. First layer 110 preferably has tensile elongation of at least 200%, more preferably at least 300% and most preferably at least 400%. First layer 110 may have a tensile strength of at least 10 MPa, more preferably at least 20 MPa and most preferably at least 30 MPa.

In some embodiments, second layer 120 comprises a pressure sensitive adhesive. The pressure sensitive adhesive may comprise acrylate, polyolefin, polyamide, polyurethane, epoxy, polyester, or any suitable mixture, copolymer, or modification thereof. Second layer 120 preferably has peel adhesion on stainless steel at 180 degree in the range of 0.1 N/mm and 4 N/mm, more preferably in the range of 0.2 N/mm and 3 N/mm, most preferably in the range of 0.3 N/mm and 2 N/mm. It is also preferred that the 120 layer provides good reworkability and clean removal.

In some embodiments, second layer 120 further comprises a crosslinker, e.g., covalent crosslinker(s) and/or ionic crosslinking agent(s). In some embodiments, the second layer 120 also comprises at least one additional component selected from the group consisting of fillers, dyes, pigments, antioxidants, UV-stabilizers, fumed silica, nanoparticles, and surface-modified nanoparticles.

In some embodiment the OLED film 100, 200, 300 and 400 could be exposed to ebeam radiation to facilitate cross-linking. The dosage of ebeam irradiation necessary to facilitate crosslinking is generally from less than 1 megarad up to 100 megarads or more. A suitable dosage of ebeam irradiation to facilitate crosslinking can be selected by those having skill in the an. FIG. 2 is a schematic cross-sectional view of OLED cushioning film 200 including first and second layers 210 and 220 disposed on a foamed layer 230. Foamed layer 230 may correspond to foamed layer 130, and first and second layers 210 and 220 may correspond to first and second layers 110 and 120 except that first layer 210 includes air-bleed channels 245 formed using structured release liner 240 which includes structured release surface 247 facing first layer 210. The structured release liner 240 can be made by embossing, for example. Embossed or otherwise structured release liners are known and are described, for example, in U.S. Pat. Nos. 6,197,397 (Sher et al.), 6,984,427 (Galkiewicz et al.) and 7,972,670 (Seitz et al.). In some embodiments, first layer 210 is a pressure sensitive adhesive and air-bleed channels 245 allow air to escape during lamination to an OLED layer. This can prevent air entrapment between the OLED layer and the cushioning film.

FIG. 3 is a schematic cross-sectional view of OLED cushioning film 300 including first and second layers 310 and 320 disposed on a foamed layer 330. Foamed layer 330 may correspond to foamed layer 130, and first and second layers 310 and 320 may correspond to first and second layers 110 and 120 except that the first and second layers 310 and 320 are each foamed. First and second layers 310 and 320 can be foamed by incorporating foaming agents as described elsewhere herein. OLED cushioning film 300 can be made by coextrusion of the first and second layers 310 and 320 and the foamed layer 330.

Any of the OLED cushioning films described herein can be attached to an active OLED layer through an adhesive layer included in the cushioning film or through an additional adhesive layer.

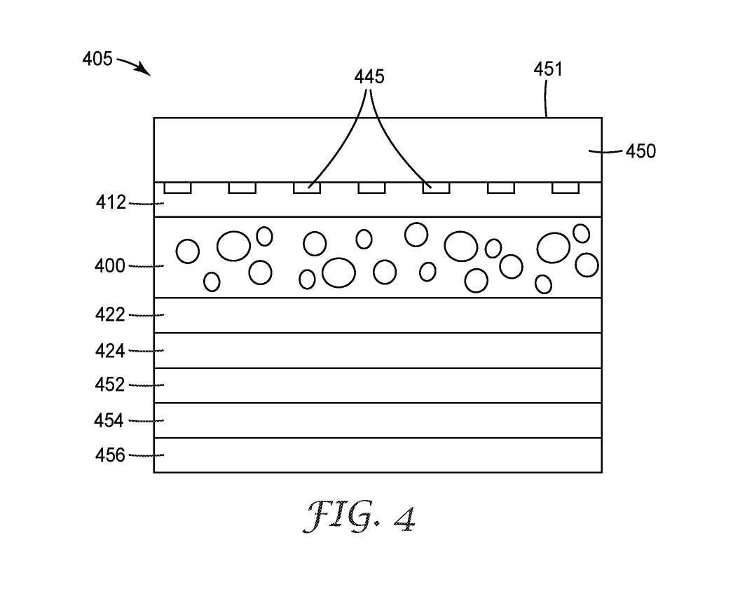

FIG. 4 is a schematic cross-sectional view of light emitting article 405 including OLED cushioning film 400 laminated to OLED layer 450 through adhesive layer 412. The OLED layer 450 includes a top surface 451 opposite the OLED cushioning film 400 and OLED layer 450 is configured to emit light though the top surface 451. In the illustrated embodiment, OLED cushioning film 400 includes a voided layer which may correspond to any of the voided layers described elsewhere herein. Adhesive layer 412 includes air-bleed channels 445. A non-adhesive layer 422 is disposed adjacent the OLED cushioning film 400 opposite adhesive layer 412. The non-adhesive layer 422 may be formed by coextrusion with OLED cushioning film 400. The adhesive layer 412 may also be formed by coextrusion with OLED cushioning film 400. The adhesive layer 412 and the non-adhesive layer 422 may be alternatively described as layers of the OLED cushioning film 400. A heat spreading layer 452 is attached to non-adhesive layer 422 through adhesive layer 424. In alternate embodiments, the non-adhesive layer 422 is omitted and adhesive layer 424 is attached directly to OLED cushioning film 400. In the illustrated embodiment, two layers (non-adhesive layer 422 and adhesive layer 424) are disposed between OLED cushioning film 400 and heat spreading layer 452. In some embodiments, one or more layers are disposed between OLED cushioning film 400 and heat spreading layer 452. Heat spreading layer 452 can be any layer suitable for spreading heat generated by OLED layer 450 such as, for example, a thermally conductive polymer or a metallic layer. An electromagnetic interference shield 456 is attached to the heat spreading layer 452 opposite the OLED cushioning film 400 with adhesive layer 454. The electromagnetic interference shield 456 may be any suitable shielding layer, such as, for example, a metal screen or foil or an ink loaded with metallic particles. In alternate embodiments, one or both of the heat spreading layer 452 and the electromagnetic interference shield 456 may be omitted or a single layer may be utilized to provide both the heat spreading and electromagnetic interference shielding functions.

A flexible OLED device can be fabricated by deposition of the organic layer onto the substrate using a method derived from inkjet printing, allowing for, in some embodiments, inexpensive roll-to-roll fabrication of printed electronics. For example, see: 1) Hebner, T. R.; Wu, C. C.; Marcy, D.; Lu, M. H.; Sturm, J. C. (1998). “Ink-jet printing of doped polymers for organic light emitting devices”. Applied Physics Letters. 72: 519; Bharathan, Jayesh; Yang, Yang (1998). “Polymer electroluminescent devices processed by inkjet printing: I. Polymer light-emitting logo”. Applied Physics Letters. 72: 2660.

Flexible OLEDs may be used in the production of bendable and flexible mobile handheld displays, electronic paper, or other bendable displays which can be integrated into smartphones, tablets, phablets, wallpapers or other curved/bendable displays.

In some embodiments, the OLED cushioning film can be part of a bendable or flexible OLED display stack that provides good damping and cushioning characteristics. Preferably in some embodiments the OLED cushioning film can withstand at least 5000 cycles of repeated bending without damaging, more preferably at least 50,000 cycles of repeated bending without damaging, and most preferably at least 500,000 cycles of repeated bending without damaging. In some embodiments the OLED cushioning film can withstand the repeated cycles of bending within a range of temperatures from −10 C to 60 C, more preferably from −20 C to 80 C.

### EXAMPLES

### Test Methods

### Ball Drop Test for Damping/Cushioning Performance

A ball drop device was used for testing cushioning/damping performance. The cushioning film sample was cut into 70 mm×70 mm testing coupon size and was sandwiched between two 5 mm thick stainless steel plates. The top plate matched the sample size. The bottom plate was big enough to cover the entire top plate so there was no exposure of the cushioning tape when looking from bottom up. A double sided tape was used on each side of the specimen to secure it on each side to the top and bottom stainless steel plate surfaces. The testing assembly was then placed on top of a force transducer. A 55 gram stainless steel ball was centered at 200 mm height above the top surface of the laminated assembly and then the ball was allowed free fall onto the assembly. The impact force was measured with the force transducer from underneath the assembly. The peak repulsive force was recorded by a computer and was used to estimate the cushioning performance. In order to do the performance evaluation, an internal reference material of known good cushioning performance was used as a benchmark. If the peak repulsive force of a test specimen was measured to be no more than 20% higher than, or lower than, that of the reference material, it was considered good cushioning performance and it was given a performance rating of 5. If the peak repulsive force was measured to be 20-40% higher than the reference material, it was considered fair cushioning performance and it was given a performance rating of 3, and if the peak repulsive force is more than 40% higher than the reference material, it was considered poor cushioning performance and it was given a performance rating of 1. The ranges and ratings are summarized in the table below.

| | % range | Rating |
|---|---|---|
| Reference Material | 100% | |
| Good Cushioning | <120% | 5 |
| Fair Cushioning | 120-140% | 3 |
| Poor Cushioning | >140% | 1 |

### Foam Quality Test

Some cushioning foam samples were visually inspected for quality. The main quality defects were large bubbles causing local holes through the film in the thickness direction. Too many of this kind of large holes reduce the foam cushioning performance due to large local variations. The quality was rated according to the number of large-hole defects per 3×3 in (7.6×7.6 cm) area. If the average number of large holes for 3 measurements was less than 10, it was considered uniform and was given a rating of 5. If the average number of large holes for 3 measurements was between 10 and 20, it was considered fairly uniform and was given a rating of 3. If the average number of large holes for 3 measurements was above 20, it was considered poor uniformity and was given a rating of 1.

| | Ave. Defects | Foam Quality Rating |
|---|---|---|
| Good Foam Quality | <10 | 5 |
| Fair Foam Quality | 10-20 | 3 |
| Poor Foam Quality | >20 | 1 |

### Porosity Measurement

Foam density was measured by conventional means, and porosity was estimated from density ratio compared to an unfoamed reference specimen.

### Comparative Example C1

On a lab twin-screw extruder, KRATON D1161 P, a linear triblock copolymer based on styrene and isoprene, with a polystyrene content of 15% (Kraton Performance Polymers, Houston, Tex.) and ENDEX 160, an aromatic hydrocarbon resin (Eastman Chemical Co., Kingsport, Tenn.) were mixed with ECOCELL-P foaming agent (Polyfil Corp., Rockaway, N.J.), with a weight ratio of 28%/70%/2%. The mixture was intermittently fed into zone 1 of the extruder to ensure a continuous operation. The extruder was equipped with a gear pump, a neck tube, and a die. The temperature profile was 176 C/176 C/193 C/193 C for extruder/gear pump/neck tube/die. The feed rate was 2.8 kg/hr. The extruded film was sandwiched in between two PET (polyethylene terephthalate) release liners using a nip and wound up in a roll. The foam thickness was controlled by adjusting the line speed and was about 100 micrometers in thickness.

### Example 1

This film was prepared the same way as Comparative Ex. C1, except the feeding ratio for KRATON D1161 P/ENDEX 160/ECOCELL-P was 48%/50%/2%.

### Example 2

This film was prepared the same way as Comparative Ex. C1, except the feeding ratio for KRATON D1161 P/ENDEX 160/ECOCELL-P was 58%/40%/2%.

### Example 3

This film was prepared the same way as Comparative Ex. C1, except the feeding ratio for KRATON D1161 P/ENDEX 160/ECOCELL-P was 68%/30%/2%.

### Example 4

This film was prepared the same way as Comparative Ex. C1, except the feeding ratio for KRATON D1161 P/ENDEX 160/ECOCELL-P was 78%/20%/2%.

### Comparative Example 2

This film was prepared the same way as Comparative Ex. C1, except the feeding ratio for KRATON D1161 P/ENDEX 160/ECOCELL-P was 88%/10%/2%.

Results are shown in Table 1.

TABLE 1

| | | | | | Foam | | Damping |
|---|---|---|---|---|---|---|---|
| Example | Rubber | Loading | Tackifier | Loading | Agent | Loading | Performance |
| C1 | D1161 | 28% | Endex 160 | 70% | ECOCELL-P | 2% | 1 |
| 1 | D1161 | 48% | Endex 160 | 50% | ECOCELL-P | 2% | 3 |
| 2 | D1161 | 58% | Endex 160 | 40% | ECOCELL-P | 2% | 5 |
| 3 | D1161 | 68% | Endex 160 | 30% | ECOCELL-P | 2% | 5 |
| 4 | D1161 | 78% | Endex 160 | 20% | ECOCELL-P | 2% | 3 |
| C2 | D1161 | 88% | Endex 160 | 10% | ECOCELL-P | 2% | 1 |

### Comparative Example C3

This film was prepared the same way as Comparative Ex. C1, except the feeding ratio for KRATON D1161 P/ENDEX 160/ECOCELL-P was 60%/40%/0%.

### Example 5

This film was prepared the same way as Comparative Ex. C1, except the feeding ratio for KRATON D1161 P/ENDEX 160/ECOCELL-P was 59%/40%/1%.

### Example 6

This film was prepared the same way as Comparative Ex. C1, except the feeding ratio for KRATON D1161 P/ENDEX 160/ECOCELL-P was 57%/40%/3%.

### Example 7

This film was prepared the same way as Comparative Ex. C1, except the feeding ratio for KRATON D1161 P/ENDEX 160/ECOCELL-P was 56%/40%/4%.

### Example 8

This film was prepared the same way as Comparative Ex. C1, except the feeding ratio for KRATON D1161 P/ENDEX 160/ECOCELL-P was 54%/40%/6%.

Results are shown in Table 2.

TABLE 2

| | | | | | Foam | | Density | | Foam | Damping |
|---|---|---|---|---|---|---|---|---|---|---|
| Example | Rubber | Loading | Tackifier | Load. | Agent | Loading | (g/cc) | Porosity | Quality | Perform. |
| C3 | D1161 | 60% | ENDEX | 40% | ECOCELL-P | 0% | 0.98 | 0% | 5 | 1 |
| | | | 160 | | | | | | | |
| 5 | D1161 | 59% | ENDEX | 40% | ECOCELL-P | 1% | 0.87 | 11% | 5 | 3 |
| | | | 160 | | | | | | | |
| 2 | D1161 | 58% | ENDEX | 40% | ECOCELL-P | 2% | 0.77 | 21% | 5 | 5 |
| | | | 160 | | | | | | | |
| 6 | D1161 | 57% | ENDEX | 40% | ECOCELL-P | 3% | 0.71 | 27% | 5 | 5 |
| | | | 160 | | | | | | | |
| 7 | D1161 | 56% | ENDEX | 40% | ECOCELL-P | 4% | 0.65 | 33% | 3 | 3 |
| | | | 160 | | | | | | | |
| 8 | D1161 | 54% | ENDEX | 40% | ECOCELL-P | 6% | 0.56 | 43% | 1 | 1 |
| | | | 160 | | | | | | | |

### Comparative Example C4

This film was prepared the same way as Comparative Ex. C1, except the feed composition was KRATON D1161 P/HIKOTACK C-90 (aromatic hydrocarbon resin, Kolon Industries, Kwacheon City, Korea)/ECOCELL-P at a feeding ratio of 58%/40%/2%.

### Comparative Example C5

This film was prepared the same way as Comparative Ex. C1, except the feed composition was KRATON D1161 P/HIKOTACK C-120 (aromatic hydrocarbon resin, Kolon Industries, Kwacheon City, Korea)/ECOCELL-P at a feeding ratio of 58%/40%/2%.

### Example 9

This film was prepared the same way as Comparative Ex. C1, except the feed composition was KRATON D1161 P/CUMAR 130 (aromatic hydrocarbon resin, Neville Chemical. Co., Pittsburgh, Pa.)/ECOCELL-P at a feeding ratio of 58%/40%/2%.

### Example 10

This film was prepared the same way as Comparative Ex. C1, except the feed composition was KRATON D1161 P/ARKON P-140 (alicyclic saturated hydrogenated hydrocarbon resin, Arakawa Chemical Industries, Ltd., Osaka, Japan)/ECOCELL-P at a feeding ratio of 58%/40%/2%.

### Example 11

This film was prepared the same way as Comparative Ex. C1, except the feed composition was KRATON D1161 P/CLEARON P150 (hydrogenated terpene resin, Yasuhara Chemical Co., Ltd., Hiroshima, Japan)/ECOCELL-P at a feeding ratio of 58%/40%/2%.

Results are shown in Table 3.

TABLE 3

| | | | | Softening | | | | |
|---|---|---|---|---|---|---|---|---|
| | | | | Point | | Foam | | Damping |
| Example | Rubber | Loading | Tackifier | (deg C.) | Loading | Agent | Loading | Perform. |
| C4 | D1161 | 58% | HIKOTACK | 95 | 40% | Ecocell-P | 2% | 1 |
| | | | C-90 | | | | | |
| C5 | D1161 | 58% | HIKOTACK | 120 | 40% | Ecocell-P | 2% | 1 |
| | | | C-120 | | | | | |
| 9 | D1161 | 58% | CUMAR 130 | 130 | 40% | Ecocell-P | 2% | 3 |
| 10 | D1161 | 58% | ARKON P140 | 140 | 40% | Ecocell-P | 2% | 5 |
| 11 | D1161 | 58% | CLEARON | 150 | 40% | Ecocell-P | 2% | 5 |
| | | | P150 | | | | | |
| 2 | D1161 | 58% | ENDEX 160 | 160 | 40% | Ecocell-P | 2% | 5 |

### Example 12

On a pilot-scale melt processing line, two twin-screw extruders were used to produce this example. The two extruders were used to feed 3 layer ABA feedblock which fed a film die. The skin and core extruders were fed with the raw materials listed below at the listed weight percentages. The overall feeding rate from skin extruder was 4 lbs/hr (1.8 kg/hr). The overall feeding rate from core extruder was 8 lbs/hr (3.6 kg/hr). The temperature set points and speed for the core extruder were: extruder barrel zones: 340 F (171 C); extruder screw speed: 250 RPM; gear pump: 340 F (171 C); necktube: 360 F (182 C). The temperature set points and speed for the skin extruder were: extruder barrel zones: 350 F (177 C); extruder screw speed: 250 RPM; gear pump: 350 F (177 C); necktube: 360 F (182 C). The melt streams from skin and core extruders are combined in the feedblock at a set point temperature of 360 F (182 C). Die was set at 360 F (182 C). The raw materials for the skin were:

45% by weight KRATON D1161 P

5% by weight IonPhasE IPE PE 0107M, a static dissipative polymer (IonPhasE Oy, Tempere, Finland)

5% by weight NUCREL 960 Ethylene-Methacrylic Acid Copolymer (DuPont Co., Wilmington, Del.)

17% by weight CUMAR 130

27% by weight ARKON P-125 (alicyclic saturated hydrogenated hydrocarbon resin, Arakawa Chemical Industries, Ltd., Osaka, Japan)

1% by weight IRGANOX 1010 sterically hindered phenolic antioxidant (BASF Corp., Florham Pk., N.J.).

The raw materials for the foam core were:

43% by weight KRATON D1161 P

5% by weight IonPhasE IPE PE 0107M

45% by weight ENDEX 160

4% by weight REMAFIN BLACK, 40% black pigment EVA masterbatch (Clariant, Charlotte, N.C.)

2% by weight ECOCELL-P

1% by weight IRGANOX 1010.

The 3-layer extrudate was cast onto a chilled roll with a first smooth PET release liner added as a carrier web. The skin layers were pressure sensitive adhesives (PSAs). The multilayer foam thickness was controlled by adjusting the line speed to get to about 100 micrometer thickness. Before the film was wound up in a roll, a second PET release liner was introduced at a lamination nip so that the second smooth PET liner was laminated to the opposite side of the sample. The double release sandwiched sample was wound up in a roll.

The resulting film had a density of 0.82 g/cc.

### Example 13

This example was produced in the same way as in Example 12 except the skin extruder was fed the following composition:

50% by weight KRATON D1161 P 5% by weight IonPhasE IPE PE 0107M

44% by weight ENDEX 160

1% by weight IRGANOX 1010

The feed rates were 4 lbs/hr (1.8 kg/hr) for the skin extruder and 8 lbs/hr (3.6 kg/hr) for the core extruder. The coextruded sample did not have finger tack.

### Example 14

This example was produced in the same way as Example 12 except that the first PET release liner was replaced with a structured paper release liner (commercially available from Loparex LLC, Hammond, Wis.) and the melt coming out the die was cast directly onto the structured liner surface made by embossing. The embossed surface had surface structures such as channels to allow the air bubbles to migrate out of the film with good lamination quality.

The sample appeared to take on the micro-pattern from the embossed liner very well.

The layered structure of various cushioning films are summarized in Table 4.

TABLE 4

| Exam- | | Skin | | Skin | |
|---|---|---|---|---|---|
| ple | Liner 1 | Layer 1 | Layer 2 | Layer 2 | Liner 2 |
| 2 | Smooth | none | Foam Layer | none | Smooth |
| 12 | Smooth | PSA Layer | Foam Layer | PSA Layer | Smooth |
| 13 | Smooth | Non-Tacky | Foam Layer | Non-Tacky | Smooth |
| | | Skin Layer | | Skin Layer | |
| 14 | Embossed | PSA Layer | Foam Layer | PSA Layer | Smooth |

The following is a list of exemplary embodiments of the present description.
Embodiment 1 is an organic light emitting diode (OLED) cushioning film comprising a foamed layer, the foamed layer comprising an olefin-styrene block copolymer at 30 to 80 weight percent and a tackifier at 15 to 60 weight percent, wherein the tackifier has a softening point of at least 130° C.
Embodiment 2 is the OLED cushioning film of Embodiment 1, further comprising a first layer attached to a first major surface of the foamed layer.
Embodiment 3 is the OLED cushioning film of Embodiment 2, wherein the first layer is an adhesive layer.
Embodiment 4 is the OLED cushioning film of Embodiment 3, further comprising a release liner disposed on the adhesive layer.
Embodiment 5 is the OLED cushioning film of Embodiment 4, wherein the release liner has a structured release surface facing the adhesive layer.
Embodiment 6 is the OLED cushioning film of Embodiment 2, wherein the first layer is a non- adhesive layer.
Embodiment 7 is the OLED cushioning film of Embodiment 2, further comprising a second layer attached to a second major surface of the foamed layer opposite the first major surface.
Embodiment 8 is the OLED cushioning film of Embodiment 7, wherein one of the first and second layers is an adhesive layer and the other of the first and second layers is a non-adhesive layer.
Embodiment 9 is the OLED cushioning film of Embodiment 7, wherein both of the first and second layers are an adhesive layers.
Embodiment 10 is the OLED cushioning film of Embodiment 7, wherein both of the first and second layers are non-adhesive layers.
Embodiment 11 is the OLED cushioning film of Embodiment 7, wherein one or both of the first and second layers are foamed.
Embodiment 12 is the OLED cushioning film of Embodiment 7, wherein each of the first and second layers has a thickness in a range of 0.05 to 1 times a thickness of the foamed layer.
Embodiment 13 is the OLED cushioning film of Embodiment 7, wherein each of the first and second layers has a thickness in a range of 0.1 to 0.5 times a thickness of the foamed layer.
Embodiment 14 is the OLED cushioning film of Embodiment 7, wherein each of the first and second layers has a thickness in a range of 0.12 to 0.35 times a thickness of the foamed layer.
Embodiment 15 is the OLED cushioning film of Embodiment 1, wherein the foamed layer has a thickness in a range of 30 micrometers to 1000 micrometers.
Embodiment 16 is the OLED cushioning film of Embodiment 1, wherein the foamed layer has a thickness in a range of 40 micrometers to 500 micrometers.
Embodiment 17 is the OLED cushioning film of Embodiment 1, wherein the foamed layer has a thickness in a range of 50 micrometers to 200 micrometers.
Embodiment 18 is the OLED cushioning film of Embodiment 1, wherein the olefin-styrene block copolymer comprises styrene blocks at 5 to 50 weight percent.
Embodiment 19 is the OLED cushioning film of Embodiment 1, wherein the olefin-styrene block copolymer comprises styrene blocks at 8 to 40 weight percent.
Embodiment 20 is the OLED cushioning film of Embodiment 1, wherein the olefin-styrene block copolymer comprises styrene blocks at 10 to 20 weight percent.
Embodiment 21 is the OLED cushioning film of Embodiment 1, wherein the olefin-styrene block copolymer comprises olefin blocks selected from the group consisting of ethylene, propylene, isoprene, octane, butylene, and copolymers thereof.
Embodiment 22 is the OLED cushioning film of Embodiment 1, wherein the softening point of the tackifier is in a range of 130° C. to 170° C.
Embodiment 23 is the OLED cushioning film of Embodiment 1, wherein the softening point of the tackifier is in a range of 130° C. to 160° C.
Embodiment 24 is the OLED cushioning film of Embodiment 1, wherein the softening point of the tackifier is in a range of 140° C. to 160° C.
Embodiment 25 is the OLED cushioning film of Embodiment 1, wherein the tackifer is selected from the group consisting of C5 hydrocarbons, C9 hydrocarbons, aliphatic resins, aromatic resins, terpenes, terpenoids, terpene phenolic resins, rosins, rosin esters, and combinations thereof.
Embodiment 26 is the OLED cushioning film of Embodiment 1, wherein the foamed layer has a density in a range of 0.5 to 0.9 g/cc.
Embodiment 27 is the OLED cushioning film of Embodiment 1, wherein the foamed layer has a density in a range of 0.55 to 0.85 g/cc.
Embodiment 28 is the OLED cushioning film of Embodiment 1, wherein the foamed layer has a density in a range of 0.6 to 0.8 g/cc.
Embodiment 29 is the OLED cushioning film of Embodiment 1, wherein the foamed layer comprises a plurality of cells, the plurality of cells having an average cell size between 5 micrometers and 100 micrometers.
Embodiment 30 is the OLED cushioning film of Embodiment 1, wherein the foamed layer comprises a plurality of cells, the plurality of cells having an average cell size between 5 micrometers and 50 micrometers.
Embodiment 31 is the OLED cushioning film of Embodiment 1, wherein the foamed layer comprises a plurality of cells, the plurality of cells having an average cell size between 5 micrometers and 30 micrometers.
Embodiment 32 is the OLED cushioning film of Embodiment 1, wherein the foamed layer has a porosity in a range of 5 to 50 percent.
Embodiment 33 is the OLED cushioning film of Embodiment 1, wherein the foamed layer has a porosity in a range of 10 to 40 percent.
Embodiment 34 is the OLED cushioning film of Embodiment 1, wherein the foamed layer comprises a plurality of cells, at least a majority of the cells being closed cells.
Embodiment 35 is a light emitting article comprising an organic light emitting diode (OLED) layer disposed on an OLED cushioning film according to any of Embodiments 1 to 34.
Embodiment 36 is the light emitting article of Embodiment 35, further comprising one or more additional layers disposed between the OLED cushioning film and the OLED layer.
Embodiment 37 is a light emitting article comprising an organic light emitting diode (OLED) layer laminated to an OLED cushioning film with an adhesive layer, the OLED cushioning film comprising a foamed layer, the foamed layer comprising an olefin-styrene block copolymer at 30 to 80 weight percent and a tackifier at 15 to 60 weight percent, wherein the tackifier has a softening point of at least 130° C., the adhesive layer having air-bleed channels adjacent the OLED layer.
Embodiment 38 is the light emitting article of any of Embodiments 35 to 37, further comprising a heat spreading layer laminated to the OLED cushioning film opposite the OLED layer.
Embodiment 39 is the light emitting article of Embodiment 38, further comprising one or more additional layers disposed between the heat spreading layer and the OLED cushioning film.
Embodiment 40 is the light emitting article of Embodiment 38, further comprising an electromagnetic interference shield laminated to the heat spreading layer opposite the OLED cushioning film.

Descriptions for elements in figures should be understood to apply equally to corresponding elements in other figures, unless indicated otherwise. Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

1. An organic light emitting diode (OLED) cushioning film comprising a foamed layer, the foamed layer comprising an olefin-styrene block copolymer at 30 to 80 weight percent and a tackifier at 15 to 60 weight percent, wherein the tackifier has a softening point of at least 130° C.

2. The OLED cushioning film of claim 1, further comprising a first layer attached to a first major surface of the foamed layer.

3. The OLED cushioning film of claim 2, wherein the first layer is an adhesive layer.

4. The OLED cushioning film of claim 3, further comprising a release liner disposed on the adhesive layer.

5. The OLED cushioning film of claim 4, wherein the release liner has a structured release surface facing the adhesive layer.

6. The OLED cushioning film of claim 2, further comprising a second layer attached to a second major surface of the foamed layer opposite the first major surface.

7. The OLED cushioning film of claim 6, wherein one or both of the first and second layers are foamed.

8. The OLED cushioning film of claim 6, wherein each of the first and second layers has a thickness in a range of 0.1 to 0.5 times a thickness of the foamed layer.

9. The OLED cushioning film of claim 1, wherein the olefin-styrene block copolymer comprises styrene blocks at 5 to 50 weight percent.

10. The OLED cushioning film of claim 1, wherein the olefin-styrene block copolymer comprises olefin blocks selected from the group consisting of ethylene, propylene, isoprene, octane, butylene, and copolymers thereof.

11. The OLED cushioning film of claim 1, wherein the tackifer is selected from the group consisting of C5 hydrocarbons, C9 hydrocarbons, aliphatic resins, aromatic resins, terpenes, terpenoids, terpene phenolic resins, rosins, rosin esters, and combinations thereof.

12. The OLED cushioning film of claim 1, wherein the foamed layer has a density in a range of 0.5 to 0.9 g/cc.

13. The OLED cushioning film of claim 1, wherein the foamed layer comprises a plurality of cells, the plurality of cells having an average cell size between 5 micrometers and 100 micrometers.

14. The OLED cushioning film of claim 1, wherein the foamed layer has a porosity in a range of 5 to 50 percent.

15. The OLED cushioning film of claim 1, wherein the foamed layer comprises a plurality of cells, at least a majority of the cells being closed cells.

16. A light emitting article comprising an organic light emitting diode (OLED) layer disposed on an OLED cushioning film according to claim 1.

17. A light emitting article comprising an organic light emitting diode (OLED) layer laminated to an OLED cushioning film with an adhesive layer, the OLED cushioning film comprising a foamed layer, the foamed layer comprising an olefin-styrene block copolymer at 30 to 80 weight percent and a tackifier at 15 to 60 weight percent, wherein the tackifier has a softening point of at least 130° C., the adhesive layer having air-bleed channels adjacent the OLED layer.

18. The light emitting article of claim 17 further comprising a heat spreading layer laminated to the OLED cushioning film opposite the OLED layer.

19. The light emitting article of claim 18, further comprising one or more additional layers disposed between the heat spreading layer and the OLED cushioning film.

20. The light emitting article of claim 18, further comprising an electromagnetic interference shield laminated to the heat spreading layer opposite the OLED cushioning film.
